(19) United States
(12) Patent Application Publication
(10) Pub. No.: US 2026/0121642 A1
(43) Pub. Date: Apr. 30, 2026

(54) Level Shifter for SIMO Converter

(71) Applicant: TEXAS INSTRUMENTS INCORPORATED, Dallas, TX (US)

(72) Inventors: Reza Sharifi, Sunnyvale, CA (US); Ramesh Balan, San Jose, CA (US)

(21) Appl. No.: 19/329,281

(22) Filed: Sep. 15, 2025

Related U.S. Application Data
(60) Provisional application No. 63/713,265, filed on Oct. 29, 2024.

(51) Int. Cl. H03K 19/0185; H02M 1/00; H02M 1/08; H02M 3/158; H03K 3/037

(52) U.S. Cl. CPC H03K 19/018521; H02M 1/009; H02M 1/08; H02M 3/158; H03K 3/037

(57) ABSTRACT

A system includes a single inductor multiple output (SIMO) DC-DC voltage converter. The voltage converter may include a transistor having a gate driver circuit. The gate driver circuit may include a voltage level shifter having an auxiliary circuit. The auxiliary circuit may be configured to force an output of the voltage level shifter during instances in which a state of the voltage level shifter may otherwise be lost.

### CROSS-REFERENCE TO RELATED APPLICATIONS

The present application claims the benefit of U.S. Provisional Patent Application 63/713,265, filed Oct. 29, 2024, the disclosure of which is hereby incorporated by reference in its entirety.

### TECHNICAL FIELD

The present application relates to circuits, generally, and more specifically to a level shifter circuit that may find use in a single inductor multiple output (SIMO) voltage converter.

### BACKGROUND

A level shifter may interface between lower voltage circuitry and higher voltage circuitry. The level shifter may translate signals between the higher voltage circuitry and the lower voltage circuitry. A level shifter may isolate and protect the lower voltage circuitry against higher voltages (from the higher voltage circuitry) that could otherwise damage the lower voltage circuitry. One application for a level shifter is the gate driver for a direct current (DC)-DC voltage converter.

### SUMMARY

In accordance to an embodiment, an electronic circuit includes: a level shifter including: a latch having first and second terminals; a high side circuit having first, second, third, and fourth terminals, where the first terminal of the high side circuit is coupled to a first reference voltage terminal, where the second terminal of the high side circuit coupled to a first supply voltage terminal, where the third terminal of the high side circuit is coupled to the first terminal of the latch, and where the fourth terminal of the high side circuit is coupled to the second terminal of the latch; and a low side circuit having first and second terminals, where the first terminal of the low side circuit is coupled to a second reference voltage terminal, and where the second terminal of the low side circuit is coupled to a second supply voltage terminal; and an auxiliary circuit including: a first terminal coupled to the second supply voltage terminal; a first transistor having first and second current path terminals and a control terminal, where the first current path terminal of the first transistor is coupled to the second terminal of the latch, where the second current path terminal of the first transistor is coupled to the first terminal of the high side circuit, and where the control terminal of the first transistor is coupled to the first terminal of the auxiliary circuit; a switch coupled between the first terminal of the auxiliary circuit and the control terminal of the first transistor; and a first diode coupled to the control terminal of the first transistor.

In accordance to an embodiment, a circuit includes: a level shifter circuit including: a latch having first and second terminals; and a high side circuit having a first, second, third, and fourth terminals, where the first terminal of the high side circuit is coupled to a first reference voltage terminal, where the second terminal of the high side circuit is coupled to a first supply voltage terminal, where the third terminal of the high side circuit is coupled to the first terminal of the latch, and where the fourth terminal of the high side circuit is coupled to the second terminal of the latch; and an auxiliary circuit configured to set a voltage level of the second terminal of the latch based on a voltage level of the first reference voltage terminal.

In accordance to an embodiment, a switching voltage converter includes: a level shifter circuit including: a latch having first and second terminals; and first and second level shifter terminals, where the first level shifter terminal is coupled to a first reference voltage terminal, and where the second level terminal is coupled to a first supply voltage terminal; and an auxiliary circuit configured to set a voltage level of the second terminal of the latch based on a voltage level of the first reference voltage terminal; a first transistor having first and second current path terminals and a control terminal, where the control terminal of the first transistor is coupled to the first terminal of the latch, where the first current path terminal of the first transistor is coupled to an input voltage terminal, and where the second current path terminal of the first transistor is coupled to a first inductor terminal of the voltage converter, and where the first level shifter terminal is coupled to the second current path terminal of the first transistor; a second transistor having first and second current path terminals, where the first current path terminal of the second transistor is coupled to a second inductor terminal of the voltage converter and the second current path terminal of the second transistor is coupled to a second reference voltage terminal; a first positive output terminal including a third transistor having first and second current path terminals, where the first current path terminal of the third transistor is coupled to the second inductor terminal, and where the second current path terminal of the third transistor is coupled to an output of the first output terminal; a first negative output terminal including a fourth transistor having first and second current path terminals, where the first current path terminal of the fourth transistor is coupled to the first inductor terminal, and where the second current path terminal of the fourth transistor is coupled to an output of the first negative output terminal; and a second negative output terminal including a fifth transistor having first and second current path terminals, where the first current path terminal of the fifth transistor is coupled to the first inductor terminal, and where the second current path terminal of the fifth transistor is coupled to an output of the second negative output terminal.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is an illustration of an example system 100, according to some embodiments;

FIG. 2 illustrates a timing diagram, for servicing the output terminal VGH, according to some embodiments;

FIG. 3 illustrates a timing diagram, for servicing the output terminal VGL2, according to some embodiments;

FIG. 4 is an illustration of an example transistor and its corresponding gate driver circuit, according to some embodiments;

FIGS. 5A-B are an illustration of an example architecture for an example level shifter circuit, according to some embodiments;

FIG. 6 is an illustration of an example timing diagram, for operation of an example auxiliary circuit, according to some embodiments; and

FIG. 7 is an illustration of an example gate driver circuit, according to various embodiments.

Corresponding numerals and symbols in different figures generally refer to corresponding parts unless otherwise indicated. The figures are drawn to clearly illustrate the relevant aspects of the preferred embodiments and are not necessarily drawn to scale.

### DETAILED DESCRIPTION

The present disclosure is described with reference to the attached figures. The figures are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

The description below illustrates various specific details to provide an in-depth understanding of several example embodiments according to the description. The embodiments may be obtained without one or more of the specific details, or with other methods, components, materials and the like. In other cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Various embodiments include a level shifter circuit, which may be used with a gate driver for a direct current to direct current (DC-DC) voltage converter. For instance, the level shifter circuit may be used for translating digital signals (e.g., digital ones and digital zeros) from a first voltage domain to a second voltage domain. The output of the level shifter (in the second voltage domain) may be applied to a gate driver, which may turn a transistor on and off to control a DC-DC converter.

An example level shifter circuit may include a latch, which has a state, and which may provide an output in the second voltage domain. In some instances, changing voltage levels within the level shifter may potentially cause the latch to lose its state. Various embodiments may include an auxiliary circuit, which forces the output of the latch to a correct value during conditions which might otherwise cause the latch to lose its state. Various embodiments may further include diodes within the level shifter circuit to prevent back current.

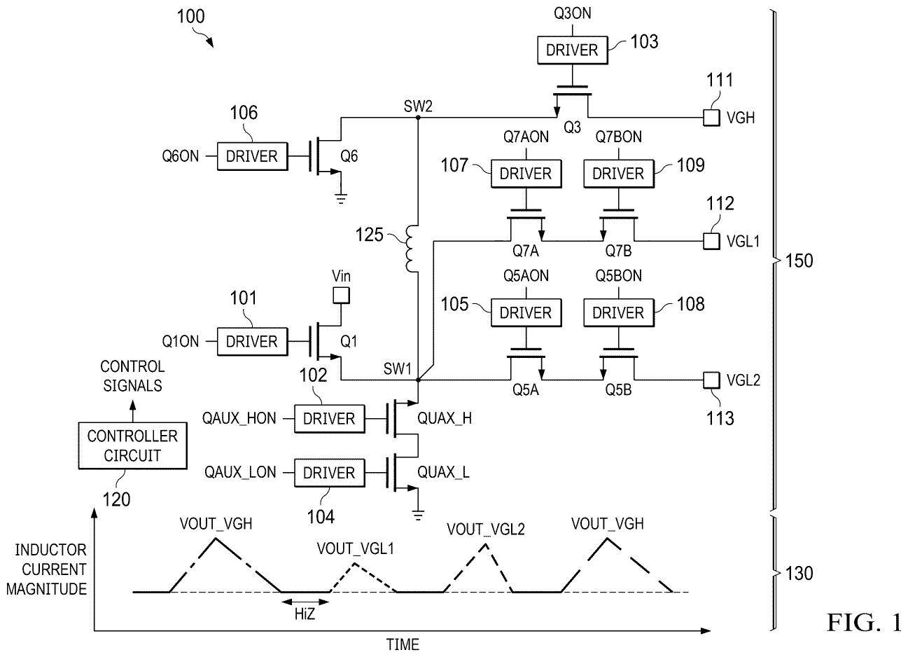

FIG. 1 is an illustration of system 100, according to some embodiments. System 100 includes DC-DC converter 150 and controller circuit 120.

In some embodiments, controller circuit 120 is configured to generate control signals (e.g., Q1ON, Q3ON, Q5AON, Q5BON, Q6ON, Q7AON, Q7BON, QAUX_HON, QAUX_LON) for controlling DC-DC converter 150. In some embodiments, controller circuit 120 may be implemented as a generic or custom processor or controller coupled to a memory and configured to execute instructions stored in such a memory. In some embodiments, control circuit 120 may be implemented using a field programmable gate array (FPGA). In some embodiments, control circuit 120 includes combinational logic, sequential logic, programmable logic (e.g., in combination with program memory), or the like, or a combination thereof. In some embodiments, control circuit 120 includes a state machine. In some embodiments, control circuit 120 includes a hardware accelerator. In some embodiments, control circuit 120 is implemented using (e.g., only) synthesized logic. Other implementations may also possible.

In some embodiments, DC-DC converter 150 includes an input terminal (Vin), and three output terminals that may function as power rails. The input terminal Vin may receive a positive voltage (e.g., from a battery), which may be 1.8 V, 3 V, 3.6 V, 5 V, or different. A first output terminal is labeled VGH, and it may be used to provide a positive voltage. A second output terminal is labeled VGL1, and it may be used to provide a first negative voltage. A third output terminal is labeled VGL2, and it may be used to provide a second negative voltage. In one example, the output voltage at VGH may be between 5V and 12V, the output voltage at VGL1 may be between −3V and −5V, and the output voltage at VGL2 may be between −5V and −7V, though the scope of implementations may include any appropriate voltage level for a given output terminal.

DC-DC converter 150 includes inductor 125, which serves all three output terminals. Thus, DC-DC converter 150 may be referred to as a single inductor multiple output (SIMO) converter.

DC-DC converter 150 includes a multitude of transistors. In the example of FIG. 1, the illustrated transistors are N type metal oxide semiconductor (NMOS) devices, though the scope of implementations may use any appropriate transistor technology. For instance, in one example, the illustrated transistors of DC-DC converter 150 may be implemented using power field effect transistors (FETs). Transistor Q1 has a gate (a type of control terminal) coupled to a gate driver circuit 101, which is configured to receive a control signal Q1ON. The drain (a type of current path terminal) of Q1 is coupled to a terminal that receives an input voltage (Vin), and the source (another type of current path terminal) of Q1 is coupled to node SW1. Transistor Q6 has a gate that is coupled to gate driver circuit 106, which is configured to receive control signal Q6ON. The drain of Q6 is coupled to the node SW2, and the source of Q6 is coupled to ground. The inductor 125 is coupled between the nodes SW1 and SW2.

Transistor QUAX_H has a gate coupled to gate driver circuit 102, which is configured to receive the control signal QUAX_HON. The source of QUAX_H is coupled to the node SW1, and the drain of QUAX_H is coupled to the drain of QUAX_L. The transistor QUAX_L has a gate that is coupled to gate driver circuit 104, which is configured to receive the control signal QUAX_LON. The source of QUAX_L is coupled to ground. When transistor Q1 is on, it couples a terminal of inductor 125 to the input voltage Vin via node SW1. When transistor Q6 is on, it may couple inductor 125 to ground via node SW2. Similarly, the transistors QUAX_H and QUAX_L may couple inductor 125 to ground via node SW1.

The output terminal labeled VGH includes transistor Q3. The transistor Q3 has a gate that is coupled to gate driver circuit 103, which is configured to receive the control signal Q3ON. The source of Q3 is coupled to the node SW2, and the drain of Q3 is coupled to pad 111. When transistor Q3 is on, it may allow current to flow between inductor 125 and the pad 111.

Transistor Q7A has a gate that is coupled to gate driver circuit 107, which is configured to receive control signal Q7AON. The drain of Q7A is coupled to the node SW1, and the source of Q7A is coupled to the source of transistor Q7B. Transistor Q7B has a gate that is coupled to gate driver circuit 109, which is configured to receive the control signal Q7BON. The drain of Q7B is coupled to the pad 112. Transistors Q7A and Q7B may be used to allow current to flow between inductor 125 and pad 112 via node SW1.

Transistor Q5 a has a gate that is coupled to gate driver circuit 105, which is configured to receive the control signal Q5AON. The drain of Q5A is coupled to the node SW1, and the source of Q5A is coupled to the source of Q5B. Transistor Q5B has a gate that is coupled to a driver circuit 108, which is configured to receive the control signal Q5BON. The drain of Q5B is coupled to the pad 113. Transistors Q5A and Q5B may be used to allow current to flow between inductor 125 and pad 113 via node SW1.

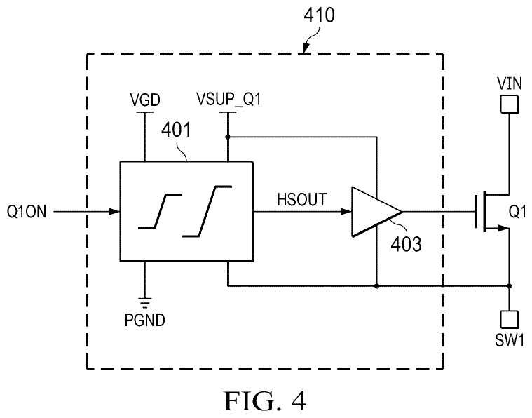

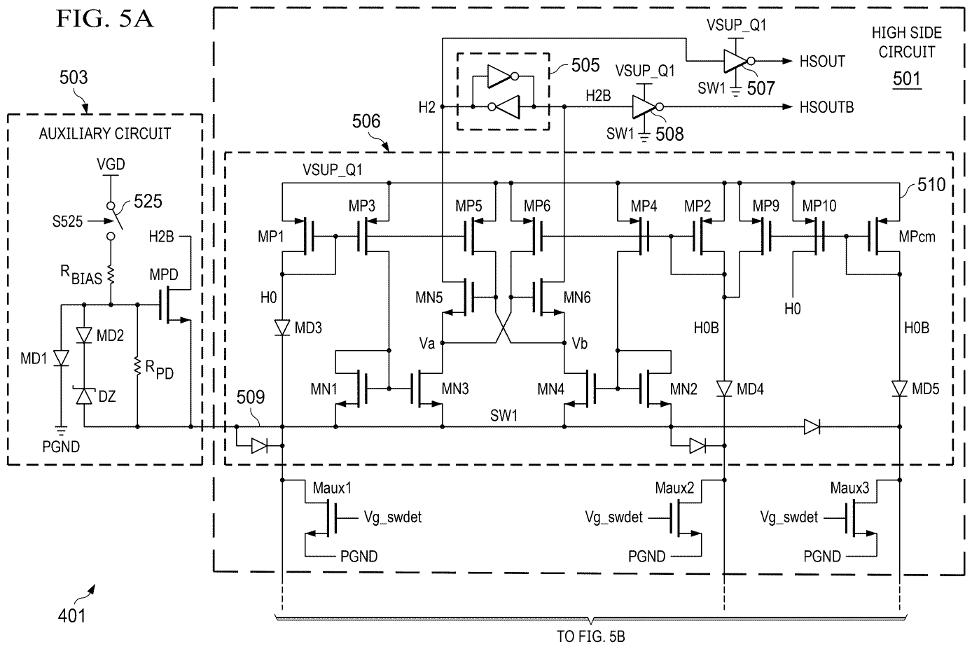

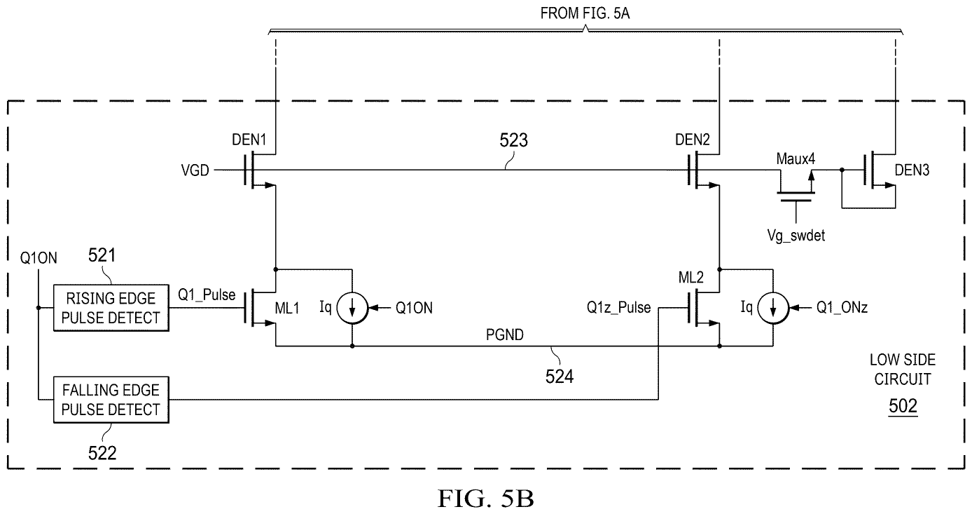

Gate driver circuit 101 may receive the control signal Q1ON, which may be a digital one or a digital zero according to a first voltage domain, and the gate driver circuit 101 may convert the control signal Q1ON to a second voltage domain. In one example, the gate driver circuit 101 may include a low-to-high level shifter, and the second voltage domain may have a greater difference between a digital one and a digital zero (high and low) versus that of the first voltage domain. The gate driver circuit 101 may then output a level-shifted version of Q1ON to the gate of transistor Q1. An example implementation of a level shifter of gate driver circuit 101 is discussed in more detail with respect to FIGS. 4 and 5.

The other gate driver circuits 102-109 are illustrated as receiving respective control signals, and it is understood that the other gate driver circuits 102-109 may similarly level shift their respective control signals and apply those respective level-shifted control signals to respective transistor gates. Furthermore, the transistors of DC-DC converter 150 may be implemented so that a digital 1 from a level-shifted control signal turns a given transistor on, and a digital 0 from a level-shifted control signal turns a given transistor off. The control signals, which are received by the gate driver circuits 101-109, may be generated by the controller circuit 120.

In this example, DC-DC converter 150 may generate time-averaged DC voltages at the pads 111-113 (some embodiments may include output capacitors at the pads 111-113 to average the output current). Furthermore, the DC-DC converter 150 may service each of the output terminals VGH, VGL1, VGL2 in a time-sharing arrangement, which is illustrated in graph 130.

Graph 130 shows an inductor current magnitude on the Y-axis and shows time on the X-axis. Earliest in time, the DC-DC converter 150 may increase and then decrease the current through inductor 125 to generate a voltage at output terminal VGH. Then there may be a high Z period before the DC-DC converter 150 increases and then decreases the current through inductor 125 to generate a voltage (VOUT_VGL1) at output terminal VGL1. The DC-DC converter 150 may then service the output terminal VGL2 before returning to servicing the output terminal VGH and repeating that pattern to create time averaged output voltages at the pads 111-113. In some embodiments, the controller circuit may service any output terminal in any order.

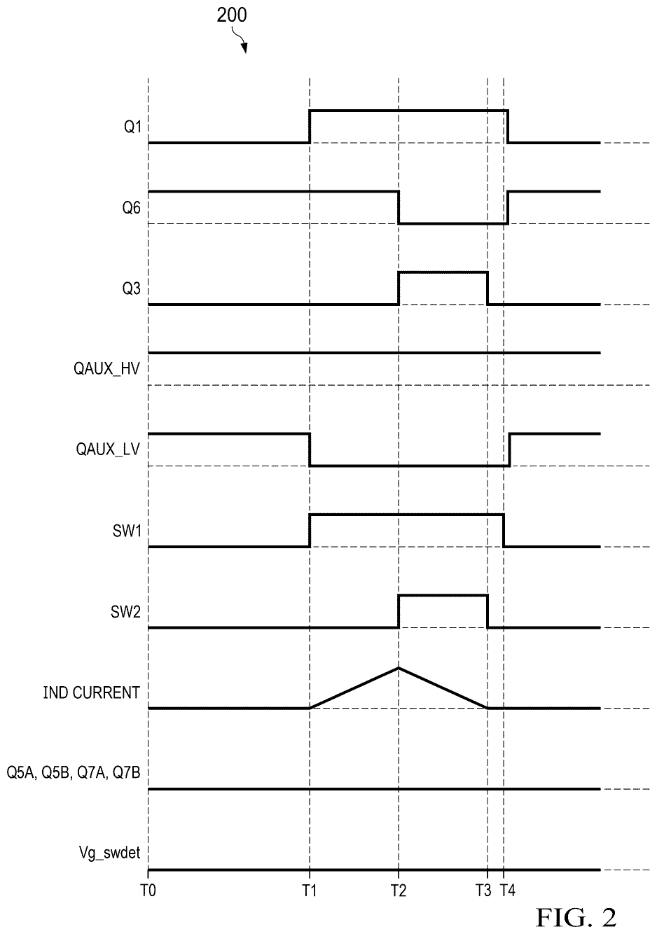

FIG. 2 illustrates a timing diagram 200, for servicing the output terminal VGH, according to some embodiments. At time TO, controller circuit 120 has turned off Q1 and Q3 and turned on Q6. QUAX_H and QUAX_L are both on. The node SW1 is at a low voltage, as is the node SW2. The time between T0 and T1 is a high Z state in which only Q6 and QAUXH and QAUXL are on; the other transistors are off to ensure that the current through the inductor 125 is zero. There is an additional control signal Vg_swdet (generated by controller circuit 120) that is low unless the voltage at node SW1 is below zero, and the control signal Vg_swdet is low for the entirety of the time in timing diagram 200 because the voltage at node SW1 is either zero or positive. Since Q1 is off, inductor 125 is not coupled to the voltage Vin, and since Q6 is on, inductor 125 is coupled to ground through node SW2.

At time T1, the controller circuit 120 turns on transistor Q1, so that inductor 125 is coupled to the voltage Vin via node SW1 and is coupled to ground via node SW2. Also, at time T1, the voltage at node SW1 goes positive because transistor Q1 has turned on. As a result, a current begins to flow through inductor 125 in the direction of SW1 to SW2. This is illustrated by an increase in the inductor current (IND Current). Also, at time T1, the voltage at node SW1 goes positive because transistor Q1 has turned on. Furthermore, the controller circuit 120 turns off transistor QUAX_L.

At time T2, controller circuit 120 turns off Q6 and turns on Q3. At time T2, the current through the inductor 125 is at a maximum, so control circuit 120 may end the magnetizing cycle and begin the demagnetizing cycle. Since transistor Q6 is off and transistor Q3 is on, the inductor current goes from the drain of Q1 to node SW1, to node SW2, and further to pad 111. Also, the voltage at node SW2 is positive and the same as the voltage level of the VGH terminal, since current flows to pad 111. Between times T2 and T3, the current through the transistor decreases to zero, and the voltage level of pad 111 goes high due to energy being delivered to the VGH terminal (e.g., 5V-12V, VOUT_VGH).

At time T3, the controller circuit 120 turns off Q3, thereby returning the voltage at node SW2 to low. At time T4, the controller circuit 120 turns off Q1, turns Q6 back on, and turns QUAX_L back on. The time T4 and following corresponds to a high Z period, such as illustrated in FIG. 1.

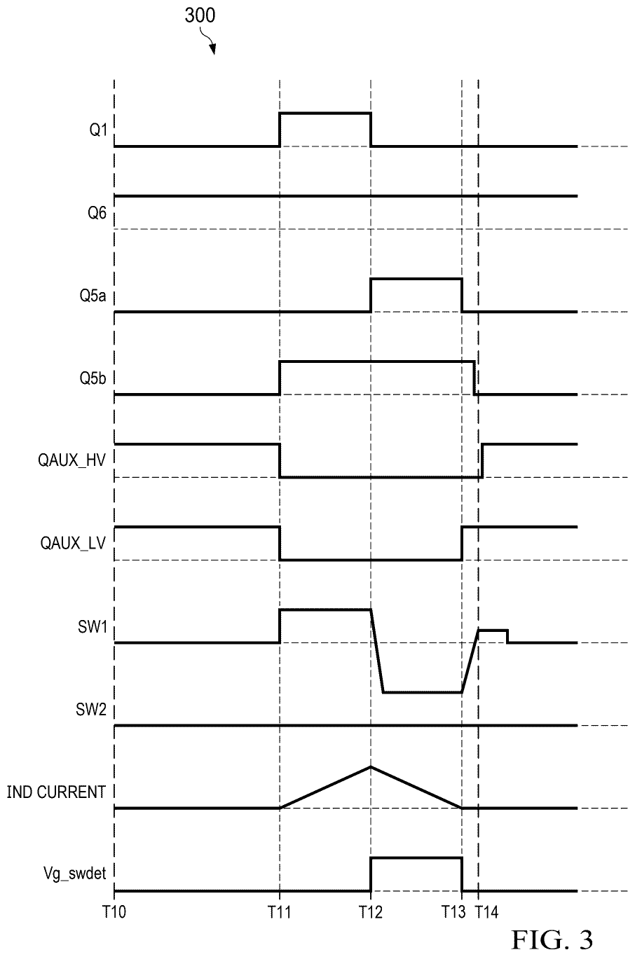

FIG. 3 illustrates a timing diagram 300, for servicing the output terminal VGL2, according to some embodiments. At time T10, controller circuit 120 causes system 100 to have a high Z state in which only Q6, QAUXH and QAUXL are on, and the other transistors are off. The voltages at nodes SW1 and SW2 are both low. Furthermore, the high Z state ensures that the current through the inductor is zero. Thus, at time T10, the inductor 125 is coupled to ground via node SW2 and transistor Q6 and is also coupled to ground via node SW1 and transistors QUAX_H and QUAX_L.

At time T11, the controller circuit 120 turns on transistor Q1 and transistor Q5B and turns off transistors QUAX_H and QUAX_L. As a result, inductor 125 is coupled to the voltage Vin via node SW1 and Q1, so the voltage at node SW1 goes high. Since transistor Q6 remains on, there is an inductor current from Vin to ground via node SW2 and Q6. The magnitude of the inductor current increases from time T11 to time T 12.

At time T12, the controller circuit turns off transistor Q1 and turns on transistor Q5A. As a result, the inductor current conducts from pad 113, through transistors Q5A and Q5B, node SW1, node SW2, to ground via Q6 The current taken from pad 113 ensures that the voltage at pad 113 is regulated to a target negative voltage. The direction of the current causes a negative pulse at the output terminal VGL2 (e.g., −5V to −7V, VOUT_VGL2). The magnitude of the current decreases from time T12 to time T13, at which point the inductor current returns to zero. During the elapsed time that the voltage at node SW1 is negative, the control circuit 120 may cause the control signal Vg_swdet to be high (e.g., digital 1).

At time T13, the control circuit 120 turns off Q5A and turns on QUAX_L. The control circuit 120 may also cause the control signal Vg_swdet to return to a low value (e.g., digital 0), and the voltage at node SW1 begins to increase.

At time T14, the control circuit 120 turns off Q5B and turns on QUAX_H. As a result, the states of the different transistors are the same as at time T10, so that the inductor 125 is coupled to ground through both nodes SW1 and SW2. The time after time T14 corresponds to a high Z period.

Following time T14, the control circuit 120 may continue to service other output terminals, such as output terminal VGL1. For instance, to service output terminal VGL1, the control circuit 120 may perform similar actions as those shown in timing diagram 300 but with the difference that transistors Q5A and Q5B remain off, and control circuit 120 may turn transistors Q7A and Q7B on and off in the same way that transistors Q5A and Q5B were turned on and off in the timing diagram 300. The result is that the control circuit 120 may cause a negative voltage pulse (e.g., −3V to −5V, VOUT_VGL1) at the output terminal VGL1.

FIG. 4 is an illustration of transistor Q1 and a gate driver circuit 410, according to some embodiments. Gate driver circuit 101 may be implemented according to the example of gate driver circuit 410. A first voltage domain may include supply voltage VGD and reference voltage PGND, where PGND may correspond to the ground reference voltage of FIG. 1. A second voltage domain may include VSUP_Q1 and the voltage at node SW1. In one example, a voltage difference between VGD and PGND may be 2V, whereas a voltage difference between VSUP_Q1 and the voltage at SW1 may be 5V. The level shifter circuit 401 may receive the control signal Q1ON in the first voltage domain and shift that control signal to the second voltage domain. The level shifted output, in the second domain, is labeled as HSOUT. The level shifted output HSOUT is received at an input of buffer 403, which uses VSUP_Q1 as its supply voltage and the voltage at SW1 as its reference voltage. In this example, the output of buffer 403 may have a same or similar voltage level as HSOUT, and the output of buffer 403 may be applied to the gate of transistor Q1. When Q1ON is at a digital 1, HSOUT is also a digital 1 level-shifted to the second voltage domain. When Q1ON is at a digital 0, HSOUT is also a digital 0 level-shifted to the second voltage domain.

Further in this example, the supply voltage VSUP_Q1 may be generated at a level of the voltage at node SW1 plus, e.g., 5V. For example, the controller circuit 120 may receive the voltage level of SW1 and output the supply voltage VSUP_Q1 at a level 5V higher. Also, as shown above with respect to FIGS. 2-3, the voltage level at node SW1 may change over time. For instance, in this example, the voltage level at node SW1 may be a lowest voltage level of VGL1 (e.g., −3V to −5V) or VGL2 (e.g., −5V to −7V), and the supply voltage VSUP_Q1 may be 5V higher than that at a given time. Of course, the scope of embodiments may be adapted for use with any voltage level values.

In some SIMO systems that service multiple negative terminals, it may be possible that the voltage level at node SW1 may go low enough to cause a level shifter to lose its state and incorrectly turn on Q1 when Q1ON is a digital zero. Various embodiments use an architecture for level shifter 401 so that level shifter 401 may output HSOUT at a correct voltage level regardless of the voltage level of the node SW1. A potential advantage may include correct and predictable operation of Q1. As a result of correct and predictable operation of Q1, Q1 may be used to control multiple output terminals, including more than one negative output terminal, such as is illustrated in FIG. 1.

Although FIG. 4 describes an arrangement for use with transistor Q1, it is understood that a similar arrangement may be used for the various gate driver circuits 102-109 of FIG. 1. In other words, the other gate driver circuits 102-109 may similarly use level shifters and buffers with appropriate control signals.

FIGS. 5A-B are an illustration of an example architecture for level shifter 401, according to some embodiments. In this example, level shifter 401 includes a high side circuit 501, a low side circuit 502, and an auxiliary circuit 503. The high side circuit 501 includes a current comparator circuit 506 and a latch 505. The latch 505 includes two cross coupled inverters, which may use VSUP_Q1 as a supply voltage and the voltage level of SW1 as a reference voltage. The latch 505 has two terminals H2 and H2B, which are complementary, that cause a value to be stored in latch 505. The voltage level of terminal H2 is input to inverter 507, and inverter 507 outputs that voltage level to generate HSOUT. Similarly, the voltage level of terminal H2B is input to inverter 508, and inverter 508 outputs that voltage level to generate HSOUTB, which is complementary to HSOUT. In this example, HSOUT and HSOUTB are complementary output signals of the level shifter 401. As noted above at FIG. 4, HSOUT may be input to a buffer (e.g., buffer 403) and used to turn transistor Q1 on and off.

The high side circuit 501 may use VSUP_Q1 as a supply voltage at terminal 510 and may use the voltage level of node SW1 as a reference voltage at terminal 509. Similarly, the low side circuit 502 may use VGD as a supply voltage at terminal 523 and may use PGND as a reference voltage at terminal 524.

High side circuit 506 includes transistor MP1, which is a PMOS transistor having its source coupled to terminal 510 and its drain coupled to a first terminal of the diode MD3. The gate of transistor MP1 is coupled to its drain. Transistor MP3 is a PMOS transistor that has a source coupled to terminal 510 and a drain coupled to the drain of NMOS transistor MN1. Transistor MN1 has its drain coupled to its gate, and the source of MN1 is coupled to terminal 509. Transistor MP5 is a PMOS transistor having its source coupled to terminal 510, its gate coupled to the gates of transistors MP1 and MP3, and the drain of MP5 is coupled to the gate of MN5. Transistor MN5 is an NMOS transistor having its drain coupled to the H2 terminal of latch 505 and its source coupled to the drain of NMOS transistor MN3. Transistor MN3 has its source coupled to terminal 509.

PMOS transistor MP6 has its source coupled to terminal 510 and its gate coupled to the gates of PMOS transistors MP4 and MP2. The drain of MP6 is coupled to the gate of NMOS transistor MN6, and the source of MN6 is coupled to the drain of NMOS transistor MN4. Furthermore, the drain of MN6 is coupled to the H2B terminal of the latch 505. The transistor MN4 has a gate coupled to the gate of NMOS transistor MN2 and a source coupled to terminal 509. PMOS transistor MP4 has its source coupled to terminal 510, its gate coupled to the gates of transistors MP6 and MP2, and its drain coupled to the drain of MN2. Transistor MN2 has its gate coupled to its drain, and the source of MN2 is coupled to terminal 509.

PMOS transistor MP2 has its gate coupled to the gates of MP6 and MP4, its source coupled to terminal 510, and its drain coupled to its gate and to a terminal of diode MD4. Diode MD4 has another terminal coupled to the drain of NMOS transistor DEN2. Similarly, the other terminal of diode MD3 is coupled to the drain of NMOS transistor DEN1.

Furthermore, the source of MN6 and drain of MN4 are coupled to the drain of MP5 and the gate of MN5. Similarly, the source of MN5 and the drain of MN3 are coupled to the drain of MP6 and the gate of MN6.

PMOS transistor MP9 has its source coupled to terminal 510 and its drain is coupled to the drain of MP2. The gate of transistor MP9 is coupled to the gates of transistors MP10 and Mpcm. PMOS transistor MP10 has its source coupled to terminal 510, its gate coupled to the gates of MP9 and Mpcm, and its drain coupled to the drain of MP1 (HO). PMOS transistor Mpcm has its source coupled to terminal 510, its drain connected to its gate, and its drain is also connected to a first terminal of diode MD5. The other terminal of diode MD5 is coupled to the drain of NMOS transistor DEN3.

High side circuit 501 also includes transistor NMOS Maux1, which has its gate coupled to controller circuit 120 to receive the control signal Vg_swdet. The source of Maux1 is coupled to ground (PGND), and the drain of Maux1 is coupled to the drain of DEN1 and a terminal of diode MD3. NMOS transistor Maux2 has its gate coupled to controller circuit 120 to receive the control signal Vg_swdet. The source of Maux2 is coupled to ground (PGND), and the drain of Maux2 is coupled to the drain of NMOS transistor DEN2. Similarly, NMOS transistor Maux3 has its gate coupled to controller circuit 120 to receive the control signal Vg_swdet. The source of Maux3 is coupled to PGND, and the drain of Maux3 is coupled to a terminal of diode MD5 and to the drain of DEN3.

The gates of transistors DEN1-DEN3 are coupled to terminal 523 to receive the supply voltage VGD. Transistor DEN1 has its source coupled to its body terminal and to the drain of NMOS transistor ML1. Transistor ML1 has its gate coupled to the rising edge of pulse detect circuit 521 to receive the control signal Q1_Pulse. The body terminal of ML1 is connected to the source of ML1 at terminal 524. Current source Iq is coupled between the drain and source of ML1 and is controlled by the control signal Q1ON. Transistor DEN2 has its body terminal coupled to its source, and the source of DEN2 is coupled to the drain of NMOS transistor ML2. The body terminal of ML2 and the source of ML2 are both coupled to the terminal 524. The gate of transistor ML2 is coupled to falling edge pulse detector circuit 522 to receive the control signal Q1z_Pulse. In this example, Q1_Pulse and Q1z_Pulse are complementary signals. There is a current source labeled Iq that is coupled between the drain and source of ML2 and is controlled by Q1_ONz, which is a complementary signal to Q1ON.

Auxiliary circuit 503 has a first input terminal coupled to supply voltage VGD and another input terminal coupled to the H2B terminal of latch 505. The input terminal coupled to VGD is further coupled to resistor Rbias via switch 525. Switch 525 is controlled by a signal labeled S525, which may be generated by controller circuit 120 and is described in more detail below. The resistor Rbias is further coupled to the gate of NMOS transistor MPD.

The gate of transistor MPD is further coupled to a terminal of diode MD1, and the other terminal of diode MD1 is coupled to ground (PGND). The gate of transistor MPD is further coupled to a terminal of diode MD2, and the other terminal of diode MD2 is connected to a terminal of Zener diode Dz. The other terminal of diode Dz is coupled to terminal 509. Resistor RPD is coupled between the gate of transistor MPD and the terminal 509. The drain of transistor MPD is coupled to the H2B terminal of latch 505, and the source of transistor MPD is coupled to the terminal 509.

Looking at the current comparator 506, it has a first current mirror, which includes transistors MP1 and MP3. There is also a second current mirror that includes transistors MN1 and MN3. A third current mirror includes transistors MP4 and MP2. A fourth current mirror includes transistors MN4 and MN2. The source of MN5 and drain of MN3 is marked as node Va, and the source of MN6 and the drain of MN4 is marked as node Vb. The node Va provides the voltage at the H2 terminal of the latch 505, and the node Vb provides the voltage at the H2B terminal of the latch 505.

When rising edge pulse detect circuit 521 detects that control signal Q1ON has a rising edge, rising edge pulse detect circuit 521 causes the control signal Q1_Pulse to go high, which results in a first current from terminal 510 to terminal 524 via MP1, DEN1, and ML1. The magnitude of the current may be set by the current source Iq. That current is mirrored between terminals 510 and 509 via transistors MP3 and MN1. That current is also mirrored through MN3 from node Va to terminal 509.

Similarly, when falling edge pulse detect circuit 522 detects that control signal Q1ON has a falling edge, falling edge pulse detect circuit 522 causes the control signal Q1z_Pulse to go high, which results in a second current from terminal 510 to terminal 524 via transistors MP2, DEN2, and ML2. The second current is mirrored between terminals 510 and 509 via transistors MP4 and MN2 and is also mirrored between node Vb and terminal 509 via transistor MN4. During operation, transistors MP9, MP10, Mpcm, and DEN3 operate to compensate for some amount of common mode current.

When the rising edge pulse detect circuit 521 detects a rising edge, rising edge pulse detect circuit 521 causes a current to flow between terminal 510 and terminal 523 via ML1, which increases an amount of current conducted from node Va to terminal 509. Therefore, the voltage level of Va may decrease relative to the voltage level of Vb, thereby setting the latch 505 with a low value at terminal H2 and a high value at terminal H2B. This may cause the value of HSOUT to be at the level of VSUP_Q1. When the falling edge pulse detect circuit 522 detects a falling edge, falling edge pulse detect circuit 522 causes a current from terminal 510 to terminal 524 via ML2, which increases an amount of current from node Vb to terminal 509. In such an instance, the voltage level of Vb may decrease relative to the voltage level of Va, thereby setting the latch 505 with a high value at terminal H2 and a low value at terminal H2B. This causes the value of HSOUT to be at the level of SW1.

In some embodiments, auxiliary circuit 503 is configured to maintain the level shifter state as active low, when SW1 goes to a negative voltage level. When SW1 is positive or 0V, auxiliary circuit 503 does not interfere the level shifter functionality in this example.

In a scenario in which the voltage level of SW1 is positive, that may cause some amount of biasing current from terminal 509 through resistor RPD and to ground via diode MD1. Additionally, switch 525 may be closed by the signal S525, which may cause further biasing current to flow from VGD to ground via Rbias and diode MD1.

Transistor MPD, diode MD1, and resistors Rbias, RPD may be selected so that the voltage level resulting from the biasing current does not cause a gate-source voltage level of MPD to be high enough to turn on MPD. When the voltage level at SW1 is zero (e.g., PGND), there may still be biasing current through resistor Rbias and MD1, and once again, the gate-source voltage level of MPD would not be high enough to turn on MPD. Diode MD2 is arranged to prevent diode Dz from being forward biased when the voltage level of SW1 is greater than the voltage level at the gate of transistor MPD.

Transistor MPD, diode MD1, and resistors Rbias and RPD may be selected so that when the voltage level at SW1 is negative (e.g., below PGND) then that may result in a gate-source voltage level of MPD to be high enough to turn on MPD. When transistor MPD turns on, the negative voltage level from SW1 is coupled to the H2B terminal of the latch 505, which may cause the terminal H2 to go high, thereby setting the latch to hold a value to cause HSOUT to be low (e.g., equal to the level of SW1). Thus, the auxiliary circuit 503 may act as a pull down circuit for the H2B terminal of the latch 505 when the voltage level of SW1 goes negative.

When the voltage level of SW1 gets to a certain negative voltage (e.g., −4V), then current may conduct from the gate of MPD through the diode MD2 to terminal 509. In such an instance, the Zener diode Dz may act as a voltage regulator to keep the voltage difference between the terminal 509 and the gate of MPD within a safe operating range for MPD.

There may be some instances in which it may not be desirable to turn on MPD even if the voltage level of SW1 goes negative. The switch 525 may be controlled by the signal S525 to further determine whether transistor MPD turns on. For instance, when the controller circuit 120 uses the S525 signal to turn off switch 525, such turning off of switch 525 may cause transistor MPD not to turn on, even in a scenario in which the voltage level of SW1 is negative. Otherwise, the control circuit 120 may use the S525 signal to keep switch 525 in an on state.

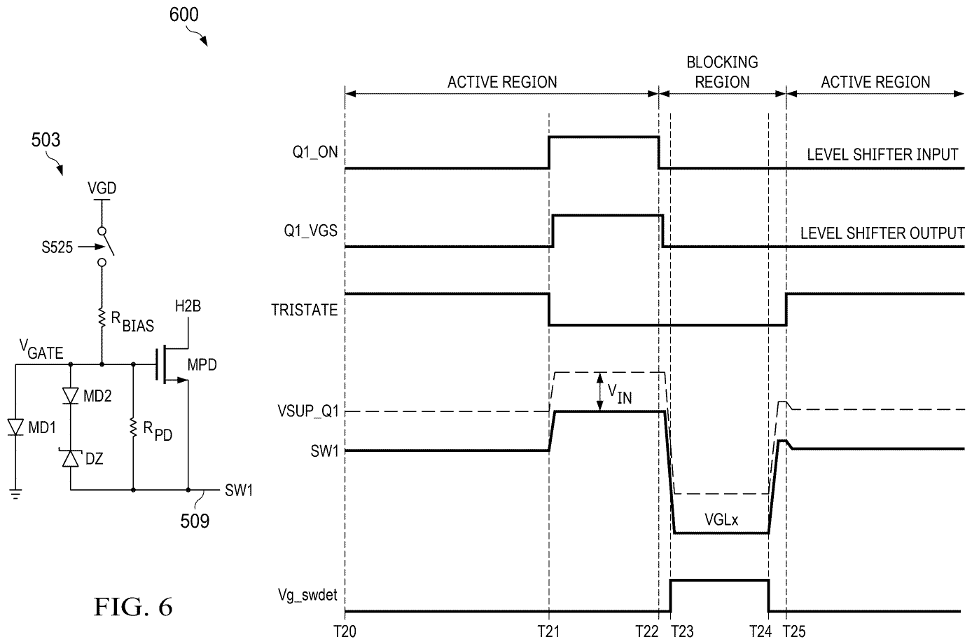

FIG. 6 is an illustration of an example timing diagram 600, for operation of the auxiliary circuit 503, according to some embodiments. In FIG. 6, the elapsed time labeled “Active Region” refers to times when transistor MPD is off, which allows the latch 505 to operate normally. The time labeled “Blocking region” refers to times when the transistor MPD is on and forces the latch 505 to attain a state in which HSOUT is low.

At time T20, the control signal Q1ON is low, and the gate-source voltage of transistor Q1 (Q1_VGS) is also low. As a result, the DC-DC converter 150 of FIG. 1 may be operating in a tri-state region. Furthermore at time T20, the voltage level at SW1 is around 0V (e.g., PGND), and the supply voltage VSUP_Q1 is 5V higher than the voltage level of SW1. Since the voltage level of SW1 is not negative, the control signal Vg_swdet is low.

At time T21, there is a rising edge of the control signal Q1ON, which causes the gate-source voltage of Q1 to go high, thereby turning transistor Q1 on. The tri-state region of the DC-DC converter 150 ends. Between times T21 and T22, the voltage level of SW1 increases so it becomes more positive, and VSUP_Q1 tracks the voltage level of SW1 by remaining at 5V higher.

At time T23, there is a falling edge of the control signal Q1ON, which causes the gate-source voltage of transistor Q1 to go low, thereby turning transistor Q1 off. The voltage level of SW1 begins to drop, eventually turning negative, which turns on transistor MPD. As noted above, when transistor MPD turns on, that forces the latch 505 to attain a state in which HSOUT is low. Furthermore, the control circuit 120 may cause the signal Vg_swdet to go high. Control circuit 120 may change the state of the signal Vg_swdet in response to detecting the level of SW1 or may change the state of the signal Vg_swdet based on timing because it may be known during design which times corresponds to negative voltage levels of SW1. In the present example, the voltage level of SW1 is negative when the DC-DC converter 150 services either one of the negative output terminals VGL1 or VGL2, and with that timing known beforehand, the controller circuit 120 may be configured to set Vg_swdet to be high during those times. The level of SW1 remains negative until time T24, at which point the controller circuit 120 may change the state of the signal Vg_swdet to be low.

Between times T23 and T24, when the level of SW1 is negative, the high level of the signal Vg_swdet causes transistors Maux1-Maux3 to turn on. The transistors Maux1-Maux3 are arranged to protect the diodes MD3-MD5. In some examples, the voltage level of terminal 510 may fall below the voltage level of terminal 524, and diodes MD3-MD5 are arranged to prevent current from conducting from terminal 524 to terminal 510 at those times. However, if the voltage difference between terminal 510 and 524 gets large enough, that may have the potential to damage diodes MD3-MD5. Transistors Maux1-Maux3 turn on when Vg_swdet goes high (e.g., when the level of SW1 is negative), thereby coupling the cathodes of diodes MD3-MD5 to ground (PGND) and protecting diodes MD3-MD5 from exceeding their break down voltages.

Transistor Maux4 is a PMOS transistor, which is controlled by the signal Vg_swdet. More specifically, transistor Maux4 is on when Vg_swdet is low and off when Vg_swdet is high. Thus, between times T23 and T24, Maux4 is off. The transistor Maux4, when it is off, prevents a short between terminal 523 and PGND at Maux3 when Maux3 is on (e.g., when the level of SW1 is negative). During times when the level of SW1 is zero or positive, Maux4 is on.

The diodes illustrated in FIG. 5A may be implemented in any suitable way. For instance, the diodes of FIG. 5A may be implemented as two-terminal devices. In another example, the diodes of FIG. 5A may be implemented as transistors having body terminal to drain coupling or the like.

At time T24, the level of SW1 reaches zero (e.g., PGND) and increases to be positive, and controller circuit 120 may cause the signal Vg_swdet to go low. At time T25, the tri-state region of operation of DC-DC converter 150 begins again. Furthermore, the blocking region of operation ends at time T25, and the active region of operation begins.

An advantage of the auxiliary circuit 503, in some embodiments, is that it may allow for use of a single level shifter circuit (e.g., level shifter circuit 401) to drive the gate of a transistor (e.g., Q1) that services multiple negative output terminals of a DC-DC converter. For instance, as shown above, DC-DC converter 150 may service three or more output terminals (e.g., VGH, VGL1, VGL2) with two or more of those output terminals being negative voltage output terminals. The use of a single level shifter circuit (e.g., versus two or more level shifter circuits) and a gate driver circuit may reduce a number of transistors on a semiconductor die, thereby decreasing cost and complexity. Furthermore, the auxiliary circuit 503 may force a value of latch 505 to cause HSOUT to be low, thereby avoiding a scenario where a low voltage of SW1 might otherwise cause latch 505 to lose state and potentially turn on transistor Q1 when Q1ON his low. In other words, the auxiliary circuit 503 may allow for more reliable operation of a DC-DC converter. Also, the implementation of diodes MD3-MD5 and transistors Maux1-Maux4 may prevent undesirable back current and shorts, thereby providing more reliable operation of a level shifter circuit.

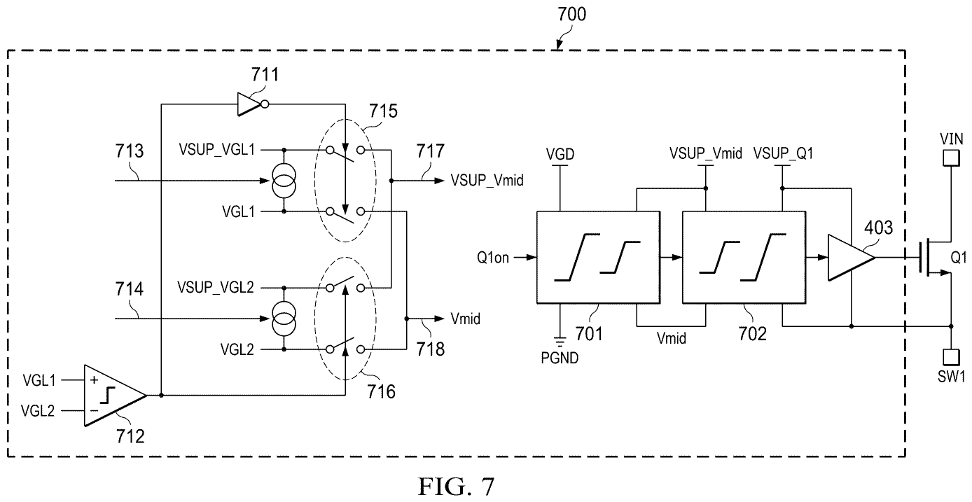

FIG. 7 is an illustration of an example gate driver circuit 700, according to various embodiments. Gate driver circuit 700 may be implemented in the DC-DC converter 150 of FIG. 1 (e.g., as gate driver circuit 101) to allow for servicing more than one negative output terminal (VGL1, VGL2). Gate driver circuit 700 includes a high-to-low level shifter 701 coupled to a low-to-high level shifter 702. The low-to-high level shifter 702 is coupled to the input of buffer 403, and the output of buffer 403 is coupled to the gate of transistor Q1. Level shifters 701 and 702 may be implemented according to any appropriate level shifter architectures.

The high to low level shifter 701 may receive the control signal Q1ON in the first voltage domain that includes VGD and PGND. Level shifter 701 then shifts the level of Q1ON to a second voltage domain that includes VSUP_Vmid and Vmid. The output of level shifter 701 is received at the input of level shifter 702. Level shifter 702 receives the level shifted Q1ON in the second voltage domain and converts from the second domain to a third voltage domain that includes VSUP_Q1 and the level of SW1. The level shifter 702 may output Q1ON in the third voltage domain to the input of the buffer 403.

The level shifters 701 and 702 may be coupled to the terminals 717 and 718. Terminal 717 provides the voltage VSUP_Vmid (a supply voltage for the second voltage domain), and terminal 718 provides the voltage Vmid (a reference voltage for the second voltage domain). Floating voltage source 713 may generate a voltage VGL1 and a voltage VSUP_VGL1 that is some constant level (e.g., 4V) higher than VGL1. Floating voltage source 714 may generate a voltage VGL2 and a voltage VSUP_VGL2 that is the same constant level (e.g., 4V) higher than VGL2.

In the example of FIG. 7, the output level of VGL1 may be either higher or lower than the output level of VGL2. The driver circuit 700 is configured to set the reference voltage Vmid to be the lowest of VGL1 and VGL2. Comparator 712 receives a voltage level for VGL2 at its inverting input and a voltage level for VGL1 at its noninverting input. The output of comparator 712 is coupled to switches 715 via inverter 711 and to switches 716. In an instance in which the level of VGL2 is lowest, the output of comparator 712 is high, which turns on switches 716 and turns off switches 715. When switches 716 are on, that couples VGL2 to terminal 718 (Vmid) and VSUP_VGL2 to VSUP_Vmid. In an instance in which the level of VGL1 is lowest, the output of comparator 712 is low, which turns on switches 715 and turns off switches 716. When switches 715 are on, that couples VGL1 to terminal 718 (Vmid) and VSUP_VGL1 to VSUP_Vmid.

Although FIG. 7 describes an arrangement for use with transistor Q1, it is understood that a similar arrangement may be used for the various gate driver circuits 102-109 of FIG. 1.

Example embodiments of the present disclosure are summarized here. Other embodiments can also be understood from the entirety of the specification and the claims filed herein.

Example 1. An electronic circuit including: a level shifter including: a latch having first and second terminals; a high side circuit having first, second, third, and fourth terminals, where the first terminal of the high side circuit is coupled to a first reference voltage terminal, where the second terminal of the high side circuit coupled to a first supply voltage terminal, where the third terminal of the high side circuit is coupled to the first terminal of the latch, and where the fourth terminal of the high side circuit is coupled to the second terminal of the latch; and a low side circuit having first and second terminals, where the first terminal of the low side circuit is coupled to a second reference voltage terminal, and where the second terminal of the low side circuit is coupled to a second supply voltage terminal; and an auxiliary circuit including: a first terminal coupled to the second supply voltage terminal; a first transistor having first and second current path terminals and a control terminal, where the first current path terminal of the first transistor is coupled to the second terminal of the latch, where the second current path terminal of the first transistor is coupled to the first terminal of the high side circuit, and where the control terminal of the first transistor is coupled to the first terminal of the auxiliary circuit; a switch coupled between the first terminal of the auxiliary circuit and the control terminal of the first transistor; and a first diode coupled to the control terminal of the first transistor.

Example 2. The electronic circuit of example 1, where the auxiliary circuit further includes: a second diode coupled to the first terminal of the auxiliary circuit; and a third diode coupled to the second diode and to the second current path terminal of the first transistor.

Example 3. The circuit of one of examples 1 or 2, where the second diode has an anode coupled to the first terminal of the auxiliary circuit and a cathode coupled to a cathode of the third diode, where an anode of the third diode is coupled to the second current path terminal of the first transistor.

Example 4. The circuit of one of examples 1 to 3, where the high side circuit includes a first current mirror having a first leg and a second leg, where the first leg of the first current mirror is coupled to the first terminal of the high side circuit and to the second terminal of the high side circuit, and the second leg of the first current mirror is coupled to the second terminal of the high side circuit and to the low side circuit, further where the second leg of the first current mirror includes a second diode having a first terminal coupled to the second terminal of the high side circuit and a second terminal coupled to the low side circuit.

Example 5. The circuit of one of examples 1 to 4, where the low side circuit includes a second transistor having first and second current path terminals and a control terminal, where the first current path terminal of the second transistor is coupled to the second diode, where the second current path terminal of the second transistor is coupled to the first terminal of the low side circuit, and where the control terminal of the second transistor is coupled to the second supply voltage terminal.

Example 6. The circuit of one of examples 1 to 5, where the high side circuit further includes a third transistor having first and second current path terminals and a control terminal, where the first current path terminal of the third transistor is coupled to the second diode and the second current path terminal of the third transistor is coupled to the second reference voltage terminal, further where the control terminal of the third transistor is coupled to a control signal.

Example 7. The circuit of one of examples 1 to 6, where the low side circuit further includes a fourth transistor having first and second current path terminals and a control terminal, where the first current path terminal of the fourth transistor is coupled to the second terminal of the high side circuit, where the second current path terminal of the fourth transistor is coupled to the control terminal of the fourth transistor, and where the control terminal of the fourth transistor is coupled to the second reference voltage terminal.

Example 8. The circuit of one of examples 1 to 7, where the low side circuit further includes a fifth transistor having first and second current path terminals and a control terminal, where the first current path terminal of the fifth transistor is coupled to the second reference voltage terminal, the second current path terminal of the fifth transistor is coupled to the control terminal of the fourth transistor, and where the control terminal of the fifth transistor is coupled to the control signal.

Example 9. The circuit of one of examples 1 to 8, where the high side circuit further includes a third diode having a first terminal and a second terminal, where the first terminal of the third diode is coupled to the second terminal of the high side circuit, and where the second terminal of the third diode is coupled to the first current path terminal of the fourth transistor.

Example 10. The circuit of one of examples 1 to 9, where the high side circuit further includes a sixth transistor having first and second current path terminals and a control terminal, where the first current path terminal of the sixth transistor is coupled to the second terminal of the third diode and to the first current path terminal of the fourth transistor, where the second current path terminal of the sixth transistor is coupled to the second reference voltage terminal, and where the control terminal of the sixth transistor is coupled to the control signal.

Example 11. The circuit of one of examples 1 to 10, further including: a second transistor having first and second current path terminals and a control terminal, where the first current path terminal of the second transistor is coupled to a third supply voltage terminal, the second current path terminal of the second transistor is coupled to the first terminal of the high side circuit, and where the control terminal of the second transistor is coupled to the first terminal of the latch.

Example 12. The circuit of one of examples 1 to 11, further including: a voltage converter including: a first inductor terminal; a second inductor terminal; a first output terminal coupled to the first inductor terminal; and a second output terminal coupled to the second inductor terminal and coupled to the second current path terminal of the second transistor.

Example 13. The circuit of one of examples 1 to 12, where the voltage converter further includes: a third output terminal coupled to the second inductor terminal and coupled to the second current path terminal of the second transistor, where the first output terminal is configured to provide a positive voltage, where the second output terminal is configured to provide a first negative voltage, and where the third output terminal is configured to provide a second negative voltage.

Example 14. The electronic circuit of one of examples 1 to 13, where the first negative voltage is different from the second negative voltage.

Example 15. The circuit of one of examples 1 to 14, further including: an inductor having a first terminal coupled to the first inductor terminal and a second terminal coupled to the second inductor terminal; and a third transistor having first and second current path terminals, where the first current path terminal of the third transistor is coupled to the first inductor terminal, and where the second current path terminal of the third transistor is coupled to a power supply terminal.

Example 16. The circuit of one of examples 1 to 15, where the second terminal of the first diode is coupled to a power supply terminal.

Example 17. A circuit including: a level shifter circuit including: a latch having first and second terminals; and a high side circuit having a first, second, third, and fourth terminals, where the first terminal of the high side circuit is coupled to a first reference voltage terminal, where the second terminal of the high side circuit is coupled to a first supply voltage terminal, where the third terminal of the high side circuit is coupled to the first terminal of the latch, and where the fourth terminal of the high side circuit is coupled to the second terminal of the latch; and an auxiliary circuit configured to set a voltage level of the second terminal of the latch based on a voltage level of the first reference voltage terminal.

Example 18. The circuit of example 17, where the auxiliary circuit is configured to set the voltage level of the second terminal of the latch to the voltage level of the first reference voltage terminal based on the voltage level of the first reference voltage terminal being below a ground reference voltage.

Example 19. The circuit of one of examples 17 or 18, where the auxiliary circuit includes: a first transistor having first and second current path terminals, where the first current path terminal of the first transistor is coupled to the second terminal of the latch and the second current path terminal of the first transistor is coupled to the first terminal of the high side circuit.

Example 20. The circuit of one of examples 17 to 19, where the auxiliary circuit is configured to turn on the first transistor based on the voltage level of the first reference voltage terminal being below a ground reference voltage.

Example 21. The circuit of one of examples 17 to 20, where the level shifter circuit includes a low-to-high level shifter circuit.

Example 22. The circuit of one of examples 17 to 21, further including: a voltage converter including: a first transistor having first and second current path terminals and a control terminal, where the control terminal of the first transistor is coupled to the first terminal of the latch, where the first current path terminal of the first transistor is coupled to an input voltage terminal, and where the second current path terminal of the first transistor is coupled to a first inductor terminal of the voltage converter, and where the first terminal of the high side circuit is coupled to the second current path terminal of the first transistor; a second transistor having first and second current path terminals, where the first current path terminal of the second transistor is coupled to a second inductor terminal of the voltage converter and the second current path terminal of the second transistor is coupled to a second reference voltage terminal; a first output terminal including a third transistor having first and second current path terminals, where the first current path terminal of the third transistor is coupled to the second inductor terminal, and where the second current path terminal of the third transistor is coupled to an output of the first output terminal; a second output terminal including a fourth transistor having first and second current path terminals, where the first current path terminal of the fourth transistor is coupled to the first inductor terminal, and where the second current path terminal of the fourth transistor is coupled to an output of the second output terminal; and a third output terminal including a fifth transistor having first and second current path terminals, where the first current path terminal of the fifth transistor is coupled to the first inductor terminal, and where the second current path terminal of the fifth transistor is coupled to an output of the third output terminal.

Example 23. The circuit of one of examples 17 to 22, further including: an inductor coupled to the first inductor terminal and to the second inductor terminal; and a controller circuit, where the controller circuit is configured to charge the inductor by: turning on the first transistor; turning on the second transistor; turning off the third transistor; turning off the fourth transistor; and turning off the fifth transistor; where the controller circuit is configured to, subsequent to charging the inductor, discharge the inductor onto the first output terminal by: turning off the second transistor; and turning on the third transistor.

Example 24. The circuit of one of examples 17 to 23, further including: an inductor coupled to the first inductor terminal and to the second inductor terminal; and a controller circuit, where the controller circuit is configured to charge the inductor by: turning on the first transistor; turning on the second transistor; turning off the third transistor; and turning on the fourth transistor; where the controller circuit is configured to, subsequent to charging the inductor, discharge the inductor onto the second output terminal by: turning off the first transistor; where the controller circuit is circuit is configured to, subsequent to charging the inductor, cause the auxiliary circuit to: set the voltage level of the second terminal of the latch based on the voltage level of the first reference voltage terminal.

Example 25. The circuit of one of examples 17 to 24, further including: an inductor coupled to the first inductor terminal and to the second inductor terminal; and a controller circuit, where the controller circuit is configured to charge the inductor by: turning on the first transistor; turning on the second transistor; turning off the third transistor; and turning on the fifth transistor; where the controller circuit is configured to, subsequent to charging the inductor, discharge the inductor onto the third output terminal by: turning off the first transistor; where the controller circuit is circuit is configured to, subsequent to charging the inductor, cause the auxiliary circuit to: set the voltage level of the second terminal of the latch based on the voltage level of the first reference voltage terminal.

Example 26. A switching voltage converter including: a level shifter circuit including: a latch having first and second terminals; and first and second level shifter terminals, where the first level shifter terminal is coupled to a first reference voltage terminal, and where the second level terminal is coupled to a first supply voltage terminal; and an auxiliary circuit configured to set a voltage level of the second terminal of the latch based on a voltage level of the first reference voltage terminal; a first transistor having first and second current path terminals and a control terminal, where the control terminal of the first transistor is coupled to the first terminal of the latch, where the first current path terminal of the first transistor is coupled to an input voltage terminal, and where the second current path terminal of the first transistor is coupled to a first inductor terminal of the voltage converter, and where the first level shifter terminal is coupled to the second current path terminal of the first transistor; a second transistor having first and second current path terminals, where the first current path terminal of the second transistor is coupled to a second inductor terminal of the voltage converter and the second current path terminal of the second transistor is coupled to a second reference voltage terminal; a first positive output terminal including a third transistor having first and second current path terminals, where the first current path terminal of the third transistor is coupled to the second inductor terminal, and where the second current path terminal of the third transistor is coupled to an output of the first output terminal; a first negative output terminal including a fourth transistor having first and second current path terminals, where the first current path terminal of the fourth transistor is coupled to the first inductor terminal, and where the second current path terminal of the fourth transistor is coupled to an output of the first negative output terminal; and a second negative output terminal including a fifth transistor having first and second current path terminals, where the first current path terminal of the fifth transistor is coupled to the first inductor terminal, and where the second current path terminal of the fifth transistor is coupled to an output of the second negative output terminal.

Example 27. The switching voltage converter of example 26, where the level shifter includes a low-to-high level shifter circuit.

Example 28. The switching voltage converter of one of examples 26 or 27, where the level shifter includes: a high side circuit having first, second, third, and fourth terminals, where the first terminal of the high side circuit is coupled to the first reference voltage terminal, where the second terminal of the high side circuit coupled to the first supply voltage terminal, where the third terminal of the high side circuit is coupled to the first terminal of the latch, and where the fourth terminal of the high side circuit is coupled to the second terminal of the latch; and a low side circuit having first and second terminals, where the first terminal of the low side circuit is coupled to the second reference voltage terminal, and where the second terminal of the low side circuit is coupled to a second supply voltage terminal.

Example 29. The switching voltage converter of one of examples 26 to 28, where the auxiliary circuit includes: a first auxiliary circuit terminal coupled to the second supply voltage terminal; a sixth transistor having first and second current path terminals and a control terminal, where the first current path terminal of the sixth transistor is coupled to the second terminal of the latch, where the second current path terminal of the sixth transistor is coupled to the first terminal of the high side circuit, and where the control terminal of the sixth transistor is coupled to the first terminal of the auxiliary circuit; a switch coupled between the first auxiliary circuit terminal and the control terminal of the sixth transistor; and a first diode coupled to the control terminal of the sixth transistor.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims.

Thus, the breadth and scope of the present invention should not be limited by any of the examples described above. Rather, the scope of the disclosure should be defined in accordance with the following claims and their equivalents.

What is claimed is:

1. An electronic circuit comprising:
a level shifter comprising:
a latch having first and second terminals;
a high side circuit having first, second, third, and fourth terminals, wherein the first terminal of the high side circuit is coupled to a first reference voltage terminal, wherein the second terminal of the high side circuit coupled to a first supply voltage terminal, wherein the third terminal of the high side circuit is coupled to the first terminal of the latch, and wherein the fourth terminal of the high side circuit is coupled to the second terminal of the latch; and
a low side circuit having first and second terminals, wherein the first terminal of the low side circuit is coupled to a second reference voltage terminal, and wherein the second terminal of the low side circuit is coupled to a second supply voltage terminal; and
an auxiliary circuit comprising:
a first terminal coupled to the second supply voltage terminal;
a first transistor having first and second current path terminals and a control terminal, wherein the first current path terminal of the first transistor is coupled to the second terminal of the latch, wherein the second current path terminal of the first transistor is coupled to the first terminal of the high side circuit, and wherein the control terminal of the first transistor is coupled to the first terminal of the auxiliary circuit;
a switch coupled between the first terminal of the auxiliary circuit and the control terminal of the first transistor; and
a first diode coupled to the control terminal of the first transistor.

2. The electronic circuit of claim 1, wherein the auxiliary circuit further comprises:
a second diode coupled to the first terminal of the auxiliary circuit; and
a third diode coupled to the second diode and to the second current path terminal of the first transistor.

3. The circuit of claim 2, wherein the second diode has an anode coupled to the first terminal of the auxiliary circuit and a cathode coupled to a cathode of the third diode, wherein an anode of the third diode is coupled to the second current path terminal of the first transistor.

4. The circuit of claim 1, wherein the high side circuit includes a first current mirror having a first leg and a second leg, wherein the first leg of the first current mirror is coupled to the first terminal of the high side circuit and to the second terminal of the high side circuit, and the second leg of the first current mirror is coupled to the second terminal of the high side circuit and to the low side circuit,
further wherein the second leg of the first current mirror includes a second diode having a first terminal coupled to the second terminal of the high side circuit and a second terminal coupled to the low side circuit.

5. The circuit of claim 4, wherein the low side circuit includes a second transistor having first and second current path terminals and a control terminal, wherein the first current path terminal of the second transistor is coupled to the second diode, wherein the second current path terminal of the second transistor is coupled to the first terminal of the low side circuit, and wherein the control terminal of the second transistor is coupled to the second supply voltage terminal.

6. The circuit of claim 5, wherein the high side circuit further comprises a third transistor having first and second current path terminals and a control terminal, wherein the first current path terminal of the third transistor is coupled to the second diode and the second current path terminal of the third transistor is coupled to the second reference voltage terminal, further wherein the control terminal of the third transistor is coupled to a control signal.

7. The circuit of claim 6, wherein the low side circuit further comprises a fourth transistor having first and second current path terminals and a control terminal, wherein the first current path terminal of the fourth transistor is coupled to the second terminal of the high side circuit, wherein the second current path terminal of the fourth transistor is coupled to the control terminal of the fourth transistor, and wherein the control terminal of the fourth transistor is coupled to the second reference voltage terminal.

8. The circuit of claim 7, wherein the low side circuit further comprises a fifth transistor having first and second current path terminals and a control terminal, wherein the first current path terminal of the fifth transistor is coupled to the second reference voltage terminal, the second current path terminal of the fifth transistor is coupled to the control terminal of the fourth transistor, and wherein the control terminal of the fifth transistor is coupled to the control signal.

9. The circuit of claim 8, wherein the high side circuit further comprises a third diode having a first terminal and a second terminal, wherein the first terminal of the third diode is coupled to the second terminal of the high side circuit, and wherein the second terminal of the third diode is coupled to the first current path terminal of the fourth transistor.

10. The circuit of claim 9, wherein the high side circuit further comprises a sixth transistor having first and second current path terminals and a control terminal, wherein the first current path terminal of the sixth transistor is coupled to the second terminal of the third diode and to the first current path terminal of the fourth transistor, wherein the second current path terminal of the sixth transistor is coupled to the second reference voltage terminal, and wherein the control terminal of the sixth transistor is coupled to the control signal.

11. The circuit of claim 1, further comprising:
a second transistor having first and second current path terminals and a control terminal, wherein the first current path terminal of the second transistor is coupled to a third supply voltage terminal, the second current path terminal of the second transistor is coupled to the first terminal of the high side circuit, and wherein the control terminal of the second transistor is coupled to the first terminal of the latch.

12. The circuit of claim 11, further comprising:
a voltage converter comprising:
a first inductor terminal;
a second inductor terminal;
a first output terminal coupled to the first inductor terminal; and
a second output terminal coupled to the second inductor terminal and coupled to the second current path terminal of the second transistor.

13. The circuit of claim 12, wherein the voltage converter further comprises:
a third output terminal coupled to the second inductor terminal and coupled to the second current path terminal of the second transistor,
wherein the first output terminal is configured to provide a positive voltage, wherein the second output terminal is configured to provide a first negative voltage, and wherein the third output terminal is configured to provide a second negative voltage.

14. The electronic circuit of claim 13, wherein the first negative voltage is different from the second negative voltage.

15. The circuit of claim 13, further comprising:
an inductor having a first terminal coupled to the first inductor terminal and a second terminal coupled to the second inductor terminal; and
a third transistor having first and second current path terminals, wherein the first current path terminal of the third transistor is coupled to the first inductor terminal, and wherein the second current path terminal of the third transistor is coupled to a power supply terminal.

16. The circuit of claim 1, wherein the second terminal of the first diode is coupled to a power supply terminal.

17. A circuit comprising:
a level shifter circuit comprising:
a latch having first and second terminals; and
a high side circuit having a first, second, third, and fourth terminals, wherein the first terminal of the high side circuit is coupled to a first reference voltage terminal, wherein the second terminal of the high side circuit is coupled to a first supply voltage terminal, wherein the third terminal of the high side circuit is coupled to the first terminal of the latch, and wherein the fourth terminal of the high side circuit is coupled to the second terminal of the latch; and
an auxiliary circuit configured to set a voltage level of the second terminal of the latch based on a voltage level of the first reference voltage terminal.

18. The circuit of claim 17, wherein the auxiliary circuit is configured to set the voltage level of the second terminal of the latch to the voltage level of the first reference voltage terminal based on the voltage level of the first reference voltage terminal being below a ground reference voltage.

19. The circuit of claim 17, wherein the auxiliary circuit comprises:
a first transistor having first and second current path terminals, wherein the first current path terminal of the first transistor is coupled to the second terminal of the latch and the second current path terminal of the first transistor is coupled to the first terminal of the high side circuit.

20. The circuit of claim 19, wherein the auxiliary circuit is configured to turn on the first transistor based on the voltage level of the first reference voltage terminal being below a ground reference voltage.

21. The circuit of claim 17, wherein the level shifter circuit comprises a low-to-high level shifter circuit.

22. The circuit of claim 17, further comprising:
a voltage converter comprising:
a first transistor having first and second current path terminals and a control terminal, wherein the control terminal of the first transistor is coupled to the first terminal of the latch, wherein the first current path terminal of the first transistor is coupled to an input voltage terminal, and wherein the second current path terminal of the first transistor is coupled to a first inductor terminal of the voltage converter, and wherein the first terminal of the high side circuit is coupled to the second current path terminal of the first transistor;
a second transistor having first and second current path terminals, wherein the first current path terminal of the second transistor is coupled to a second inductor terminal of the voltage converter and the second current path terminal of the second transistor is coupled to a second reference voltage terminal;
a first output terminal including a third transistor having first and second current path terminals, wherein the first current path terminal of the third transistor is coupled to the second inductor terminal, and wherein the second current path terminal of the third transistor is coupled to an output of the first output terminal;
a second output terminal including a fourth transistor having first and second current path terminals, wherein the first current path terminal of the fourth transistor is coupled to the first inductor terminal, and wherein the second current path terminal of the fourth transistor is coupled to an output of the second output terminal; and
a third output terminal including a fifth transistor having first and second current path terminals, wherein the first current path terminal of the fifth transistor is coupled to the first inductor terminal, and wherein the second current path terminal of the fifth transistor is coupled to an output of the third output terminal.

23. The circuit of claim 22, further comprising:
an inductor coupled to the first inductor terminal and to the second inductor terminal; and
a controller circuit, wherein the controller circuit is configured to charge the inductor by:
turning on the first transistor;
turning on the second transistor;
turning off the third transistor;
turning off the fourth transistor; and
turning off the fifth transistor;
wherein the controller circuit is configured to, subsequent to charging the inductor, discharge the inductor onto the first output terminal by:
turning off the second transistor; and
turning on the third transistor.

24. The circuit of claim 22, further comprising:
an inductor coupled to the first inductor terminal and to the second inductor terminal; and
a controller circuit, wherein the controller circuit is configured to charge the inductor by:
turning on the first transistor;
turning on the second transistor;
turning off the third transistor; and
turning on the fourth transistor;
wherein the controller circuit is configured to, subsequent to charging the inductor, discharge the inductor onto the second output terminal by:
turning off the first transistor;
wherein the controller circuit is circuit is configured to, subsequent to charging the inductor, cause the auxiliary circuit to:
set the voltage level of the second terminal of the latch based on the voltage level of the first reference voltage terminal.

25. The circuit of claim 22, further comprising:
an inductor coupled to the first inductor terminal and to the second inductor terminal; and
a controller circuit, wherein the controller circuit is configured to charge the inductor by:
turning on the first transistor;
turning on the second transistor;
turning off the third transistor; and
turning on the fifth transistor;
wherein the controller circuit is configured to, subsequent to charging the inductor, discharge the inductor onto the third output terminal by:
turning off the first transistor;
wherein the controller circuit is circuit is configured to, subsequent to charging the inductor, cause the auxiliary circuit to:
set the voltage level of the second terminal of the latch based on the voltage level of the first reference voltage terminal.
